(19) United States
(12) Patent Application Publication
(10) Pub. No.: US 2011/0244636 A1
(43) Pub. Date: Oct. 6, 2011

(54) MANUFACTURING METHOD OF SEMICONDUCTOR CHIP-EMBEDDED WIRING SUBSTRATE

(75) Inventor: Kenji KONDO, Anjo-city (JP)

(73) Assignee: DENSO CORPORATION, Kariya-city (JP)

(21) Appl. No.: 13/009,898

(22) Filed: Jan. 20, 2011

(30) Foreign Application Priority Data
Apr. 2, 2010 (JP) 2010-86348

(51) Int. Cl. H01L 21/56

(52) U.S. Cl. 438/127; 257/E21.502

(57) ABSTRACT

With respect to a substrate including a first film, on a surface of which a pad is formed, a second film made of thermoplastic resin is a thermal compression bonded to a pad formation surface of the substrate. A stud bump formed on a semiconductor chip is stuffed into the second film while melting the second film and is pressure welded to the pad by application of pressure and heat. The melted second film seals between the semiconductor chip and the substrate. Then, multiple resin films are stacked with the substrate and the second film to form a stacked body. In a pressurizing and heating process, the multiple resin films, the substrate and the second film are integrated at one time so that the stud bump is bonded to the pad.

### CROSS REFERENCE TO RELATED APPLICATION

The present application is based on Japanese Patent Application No. 2010-86348 filed on Apr. 2, 2010, the disclosure of which is incorporated herein by reference.

### FIELD OF THE INVENTION

The present invention relates to a manufacturing method of a semiconductor chip-embedded wiring substrate.

### BACKGROUND OF THE INVENTION

Conventionally, as a manufacturing method of a component-embedded substrate, in which a wiring part is formed and an electronic component is embedded in an insulating substrate including thermoplastic resin, a method described in JP-A-2007-324550 corresponding to US 2008/017409 is well known.

According to the manufacturing method, multiple resin films including a resin film having a conductive pattern on a surface thereof and a resin film having a via hole filled with conductive paste are stacked such that the electronic component is embedded and a stacked body is formed.

Then, the stacked body is pressurized and heated from upper and lower sides thereof to soften thermoplastic resin consisting the resin films, and thereby, the resin films are bonded to each other and integrated at one time, and the electronic component is sealed. In addition, the conductive paste filled in the via hole is sintered to form an interlayer connecting portion (conductive composition). The interlayer connecting portion connects an electrode of the electronic component and a corresponding pad (conductive pattern), or between the adjacent conductive patterns.

Accordingly, a multilayer substrate in which an electronic component is embedded can be formed at one time by application of pressure and heat, and a manufacturing process can be simplified.

By the way, in a semiconductor chip (IC chip) in which an element is accumulated, a distance between adjacent electrodes has become smaller and smaller (what is called, fine pitch) so as to handle high integration and high speed of an element and suppress the increase in size of a semiconductor chip (substrate in which the semiconductor chip is embedded). Thus, in the case where a semiconductor chip (bare chip) is applied as an embedded electric component and flip-chip mounting is performed without rewiring, the via hole having a very small diameter (e.g., diameter of about several μm to 10 μm) should be formed so as to secure an electrically insulating property between the adjacent interlayer connecting portions. Therefore, it becomes difficult to form a via hole and fill a via hole with conductive paste by the above-described method. Moreover, since the amount of conductive paste to be filled is small, it is difficult to ensure the sufficient amount of conductive particles for diffusion bonding to metal constituting the electrode of the semiconductor chip and the pad of the substrate.

On the other hand, the following method may be applied. A bump is formed on an electrode of a semiconductor chip and flip-chip mounting of the bump to a pad of a substrate is performed. As described in JP-A-2001-60602, if the bump is directly bonded to the pad (electrode) by application of pressure and heat, an electrically insulating property can be improved with accommodating fine pitch.

However, as described in JP-A-2001-60602, in order to directly bond the bump to the pad, predetermined time as pressurizing and heating time becomes necessary. Thus, time to form a semiconductor chip-embedded wiring substrate (cycle time) may be lengthened.

### SUMMARY OF THE INVENTION

In view of the above-described problem, it is an object of the present invention to provide a manufacturing method of a semiconductor chip-embedded wiring substrate that can simplify a manufacturing process and shorten manufacturing time.

According to a first aspect of the present invention, a manufacturing method of a semiconductor chip-embedded wiring substrate includes: stacking a plurality of resin films and a plurality of thermoplastic resin films including thermoplastic resin to form a stacked body, wherein the plurality of resin films include a resin film having a conductive pattern on a surface thereof and a resin film having a via hole filled with a conductive paste, at least one of the plurality of resin films is located between adjacent two thermoplastic resin films, an electrode formation surface of a semiconductor chip contacts one of the plurality of thermoplastic resin films and an opposite surface of the electrode formation surface of the semiconductor chip contacts another one of the plurality of thermoplastic resin films, and the semiconductor chip is sandwiched between the one of the plurality of thermoplastic resin films and the another one of the plurality of thermoplastic resin films; pressurizing and heating the stacked body from upper and lower sides of the stacked body in a stacking direction to form a wiring part including the conductive pattern and a sintered body formed by sintering conductive particles in the conductive paste, wherein the plurality of thermoplastic resin films are softened to integrate the plurality of resin films with the plurality of thermoplastic resin films at one time and seal the semiconductor chip; attaching a second film to a pad formation surface of a substrate including a first film, on a surface of which a pad is formed as a part of the conductive pattern, to cover the pad of the first film with the second film by heating and pressurizing the second film before the stacking, wherein the first film serves as one of the plurality of resin films and the second film serves as one of the plurality of thermoplastic resin films; and flip-chip mounting the semiconductor chip on the substrate by heating and pressurizing the semiconductor chip at a temperature equal to or higher than a melting point of the thermoplastic resin constituting the second film, wherein a stud bump formed on an electrode of the semiconductor chip is stuffed into the second film while melting the second film and is pressure welded to the pad, and the melted second film seals between the semiconductor chip and the substrate before the stacking. The plurality of resin films and the plurality of thermoplastic resin films other than the one of the plurality of resin films constituting the substrate including the first film and the second film are stacked with the substrate and the second film to form the stacked body in the stacking. The stud bump is directly bonded to the pad in the pressurizing and heating the stacked body.

According to the present invention, the multiple resin films and the multiple thermoplastic resin films are stacked to form a stacked body such that at least one of the resin films is located between the adjacent two thermoplastic resin films, and the electrode formation surface of the semiconductor chip contacts the one of the thermoplastic resin films and the opposite surface of the electrode formation surface of the semiconductor chip contacts the another one of the thermoplastic resin films. Thus, by softening the thermoplastic resin films by application of pressure and heat, the resin films can be integrated with the thermoplastic resin films at one time, and the semiconductor chip can be sealed with at least the thermoplastic films adjacent to the semiconductor chip. Furthermore, the conductive particles in the conductive paste are sintered by the application of pressure and heat to form the sintered body, and the wiring part can be formed by the sintered body and the conductive pattern. Thus, the manufacturing process can be simplified.

The resin films may include a thermosetting resin film including thermosetting resin. In the pressurizing and heating, the thermoplastic resin films are softened to integrate the resin films and the thermoplastic resin films. Thus, in the stacked body, at least one of the resin films needs to be located between the adjacent two thermoplastic resin films.

As the thermoplastic resin film except the second film made of thermoplastic resin, a film including inorganic material such as glass fiber with thermoplastic resin can be used. The same is true in the thermosetting resin. As the first film, a film including thermoplastic resin or a film including thermosetting resin can be used.

Before the stacking, the second film formed by the thermoplastic resin film is arranged between the semiconductor chip and the substrate including the first film, and the second film is heated and pressurized at the temperature equal to or higher than the melting point of the thermoplastic resin. While the temperature is increased to be equal to or higher than the melting point of thermoplastic resin, thermoplastic resin constituting the second film has fluidity, the thermoplastic resin located between the stud bump and the pad moves by application of pressure, and the stud bump directly contacts the pad so that the stud bump and the pad can be in a pressure welding state.

At this time, since the thermoplastic resin having the fluidity by the application of heat seals between the semiconductor chip and the substrate including a periphery of a connecting portion of the stud bump and the pad, an electrically insulating property between the respective connecting portions can be obtained. Moreover, connection reliability at the connecting portion can be improved.

Moreover, when the stud bump and the pad are in the pressure welding state, the flip-chip mounting (application of heat and pressure) is terminated, and the stud bump and the pad are in a bonding state by the application of pressure and heat in the pressurizing and heating. In this manner, since the stud bump and the pad are in the bonding state by using the heat and pressure in the pressurizing and heating, compared with the pressure welding state, the electrically connection reliability of the electrode of the semiconductor chip and the pad can be improved.

In the flip-chip mounting, the stud bump and the pad are in the pressure welding state, and the stud bump and the pad are in the bonding state by using the heat and pressure in the pressurizing and heating. Thus, manufacturing time can be shortened compared with a method in which the pressurizing and heating are performed after the stud bump and the pad are in the bonding state in the flip-chip mounting.

If the stud bump is not brought into contact with the pad before the stacking and the stud bump is brought into contact with the pad to be in the bonding state in the pressurizing and heating, it becomes difficult for the stud bump to be stuffed into the second film. As a result, the thermoplastic resin may remain between the stud bump and the pad. In contrast, since the stud bump and the pad are in the pressure welding state before the stacking in the present invention, the stud bump and the pad can reliably be in the bonding state by using the heat and pressure of the pressurizing and heating.

Therefore, the manufacturing process of the semiconductor chip-embedded wiring substrate can be simplified and the manufacturing time (cycle time) can be shortened.

According to a second aspect of the present invention, a manufacturing method of a semiconductor chip-embedded wiring substrate includes: stacking a plurality of resin films and a plurality of thermoplastic resin films including thermoplastic resin to form a stacked body, wherein the plurality of resin films include a resin film having a conductive pattern on a surface thereof and a resin film having a via hole filled with a conductive paste, at least one of the plurality of resin films is located between adjacent two thermoplastic resin films, an electrode formation surface of a semiconductor chip contacts one of the plurality of thermoplastic resin films and an opposite surface of the electrode formation surface of the semiconductor chip contacts another one of the plurality of thermoplastic resin films, and the semiconductor chip is sandwiched between the one of the plurality of thermoplastic resin films and the another one of the plurality of thermoplastic resin films; pressurizing and heating the stacked body from upper and lower sides of the stacked body in a stacking direction to form a wiring part including the conductive pattern and a sintered body formed by sintering conductive particles in the conductive paste, wherein the plurality of thermoplastic resin films are softened to integrate the plurality of resin films with the plurality of thermoplastic resin films at one time and seal the semiconductor chip; and flip-chip mounting the semiconductor chip on a substrate including a first film that serves as one of the plurality of resin films by heating and pressurizing the semiconductor chip, wherein a second film that serves as one of the plurality of thermoplastic resin films is attached to a pad formation surface of the substrate including the first film, on a surface of which a pad is formed as a part of the conductive pattern, to cover the pad of the first film with the second film, the second film has a through-hole at a position corresponding to the pad, the semiconductor chip is heated and pressurized at a temperature equal to or higher than a melting point of the thermoplastic resin constituting the second film so that a stud bump formed on an electrode of the semiconductor chip is pressure welded to the pad through the through-hole and the melted second film seals between the semiconductor chip and the substrate before the stacking. The plurality of resin films and the plurality of thermoplastic resin films other than the one of the plurality of resin films constituting the substrate including the first film and the second film are stacked with the substrate and the second film to form the stacked body in the stacking. The stud bump is directly bonded to the pad in the pressurizing and heating the stacked body.

By using such a method, the similar effects to the manufacturing method according to, the first aspect of the present invention can be obtained.

According to the present invention, the through hole corresponding to the pad is formed in advance in the second film before the flip-chip mounting. Thus, if heat quantity is the same, the pressure welding state between the stud bump and the pad and the sealing structure by the second film can be formed in a short time, compared with the method described in the first aspect of the present invention. That is, heating and pressurizing time in the flip-chip mounting, therefore, the manufacturing time of the semiconductor chip-embedded wiring substrate can be shortened.

Furthermore, if the heating and pressurizing time and a pressurized condition are the same, the pressure welding state between the stud bump and the pad can be obtained with low heat quantity, compared with the method described in the first aspect of the invention.

### BRIEF DESCRIPTION OF THE DRAWINGS

The above and other objects, features and advantages of the present invention will become more apparent from the following detailed description made with reference to the accompanying drawings. In the drawings:

FIG. 1 is a cross-sectional view showing a semiconductor chip-embedded wiring substrate formed by a manufacturing method according to a first embodiment of the present invention;

FIG. 2 is a cross-sectional view showing resin films, which are to be stacked on a substrate on which a semiconductor chip is mounted, in a preparing process of the manufacturing process of the semiconductor chip-embedded wiring substrate shown in FIG. 1;

FIGS. 3A to 3D are cross-sectional views showing a process for flip-chip mounting the semiconductor chip on the substrate, of the manufacturing process of the semiconductor chip-embedded wiring substrate shown in FIG. 1;

FIG. 4 is a plan view showing a state where a second film is attached to a pad formation surface of the substrate in the process shown in FIG. 3A;

FIG. 5 is a cross-sectional view showing a stacking process of the manufacturing process of the semiconductor chip-embedded wiring substrate shown in FIG. 1;

FIG. 6 is a cross-sectional view showing a pressurizing and heating process of the manufacturing process of the semiconductor chip-embedded wiring substrate shown in FIG. 1;

FIG. 7A is a plan view showing a state where a second film is attached to a pad formation surface of a substrate in a process for flip-chip mounting a semiconductor chip on the substrate, of a manufacturing process according to a second embodiment of the present invention;

FIG. 7B is a cross-sectional view taken along the line VIIB-VIIB of FIG. 7A;

FIG. 8A is a plan view showing a modified example of a state where a second film is attached to a pad formation surface of a substrate; and

FIG. 8B is a cross-sectional view taken along the line VIIIB-VIIIB of FIG. 8A.

### DETAILED DESCRIPTION OF THE PREFERRED EMBODIMENTS

The present invention has the following characterizing portions. In forming a semiconductor chip-embedded wiring substrate, steps 1) and 2) are taken. 1) A semiconductor chip (bare IC chip), on which a stud bump is formed, is flip-chip mounted on a substrate including a first film, on which a pad is formed, through a second film made of thermoplastic resin. 2) After the flip-chip mounting, the substrate on which the semiconductor chip is mounted is embedded in the wiring substrate when forming the wiring substrate by a lump-sum stacking method known as PALAP. In addition, a connection state between the stud bump and the pad is a characterizing portion.

Therefore, regarding a basic configuration and a manufacturing method of the wiring substrate/the configuration of PALAP that has been applied by the present applicant can be suitably used unless otherwise noted. In addition PALAP is a registered trademark of Denso Corporation.

### First Embodiment

Hereinafter, embodiments of the present invention will be described with reference to drawings. A thickness direction of an insulating substrate 20 (in other words, a stacking direction of multiple resin films) is referred to as a thickness direction, and a direction perpendicular to the thickness direction is referred to as a perpendicular direction. In addition, a thickness indicates a thickness along the thickness direction, unless otherwise noted.

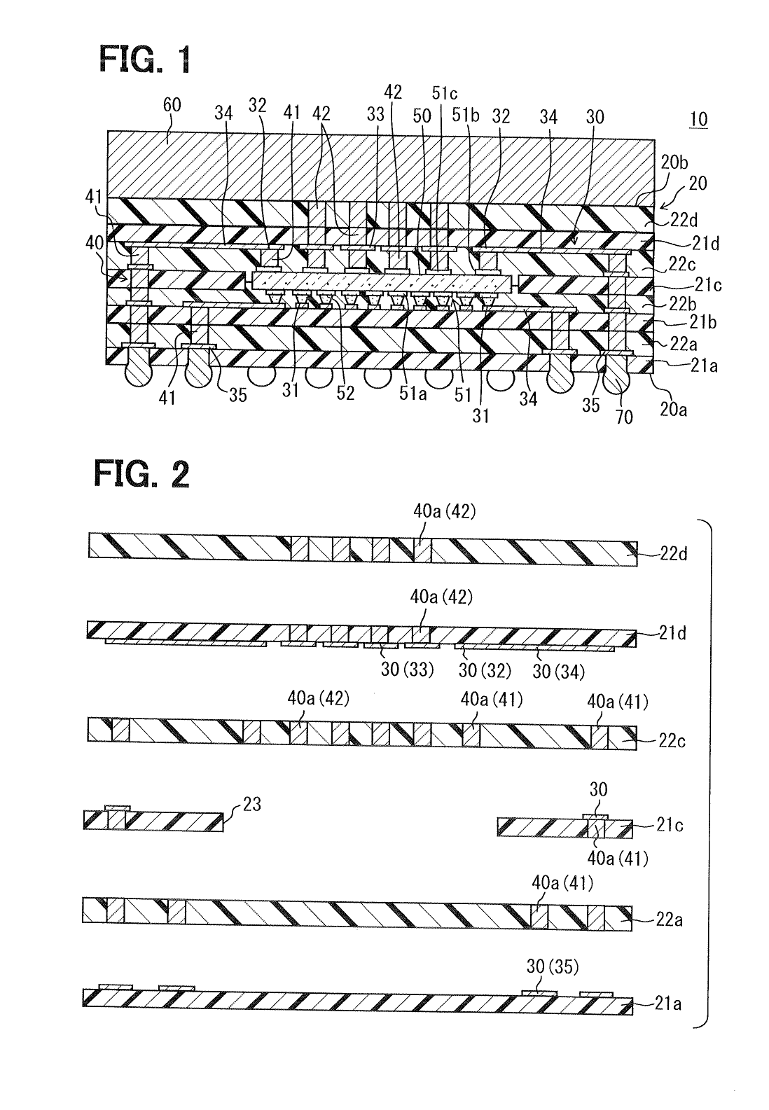

A semiconductor chip-embedded wiring substrate 10 (i.e., semiconductor device hereinafter referred to as a wiring substrate 10) shown in FIG. 1 includes the insulating substrate 20, a conductive pattern 30 and an interlayer connecting portion 40 which are formed in the insulating substrate 20, and a semiconductor chip 50 which is buried, that is, embedded in the insulating substrate 20, as basic components of a semiconductor chip-embedded wiring substrate. In addition to the above-described components, the wiring substrate 10 shown in FIG. 1 includes a heat releasing member 60.

The insulating substrate 20 is made of electrical insulating material. In the example shown in FIG. 1, the insulating substrate 20 fulfills a function to hold the conductive pattern 30, the interlayer connecting portion 40, the semiconductor chip 50 and the heat releasing member 60, as a substrate. Furthermore, the insulating substrate 20 fulfills a function to hold and protect the semiconductor chip 50 in an inside thereof.

The insulating substrate 20 is mainly made of resin, which includes at least thermoplastic resin as the resin. Multiple resin films including thermoplastic resin films are stacked, and bonded/integrated by application of pressure and heat. Since thermoplastic resin can withstand a high temperature and softened thermoplastic resin is used as adhesive and a sealing member when forming the insulating substrate 20 at one time by a pressurizing and heating process described below, the insulating substrate 20 includes thermoplastic resin.

Thus, the multiple resin films include thermoplastic resin films which are arranged at least every other film in a stacked state. For example, the multiple resin films may include only thermoplastic resin films or includes thermosetting resin films together with thermoplastic resin films.

As the thermoplastic resin film, at least one of a film, which includes inorganic material such as glass fiber and aramid fiber with thermoplastic resin, and a film made of thermoplastic resin, which does not include inorganic material, can be used. Similarly, as the thermosetting resin film, at least one of a film, which includes the above-described inorganic material with thermosetting resin, and a film made of thermosetting resin, which does not include inorganic material, can be used.

As shown in FIG. 1, in the insulating substrate 20 of the present embodiment, eight resin films, i.e., a thermosetting resin film 21a, a thermoplastic resin film 22a, a thermosetting resin film 21b, a thermoplastic resin film 22b, a thermosetting resin film 21c, a thermoplastic resin film 22c, a thermosetting resin film 21d and a thermoplastic resin film 22d are stacked in this order from a side of one surface 20a in the thickness direction. That is, the thermoplastic resin films and the thermosetting resin films are stacked alternately so that the insulating substrate 20 is formed.

As the thermosetting resin films 21a to 21d, a film made of thermosetting polyimide (PI), which does not include inorganic material such as glass fiber, is used. In contrast, as the thermoplastic resin films 22a to 22d, a resin film made of 30 weight percent of polyether ether ketone (PEEK) and 70 weight percent of polyetherimide (PEI), which does not include inorganic material such as glass fiber and inorganic filler for adjusting a linear expansion coefficient, is used.

In the above-described resin films, the thermosetting resin film 21b corresponds to a substrate (i.e., a first film) on which the semiconductor chip 50 is mounted, and the thermoplastic resin film 22b corresponds to a second film that seals between the semiconductor chip 50 and the thermosetting resin film 21b as the substrate.

Conductive foil is patterned so that the conductive pattern 30 is formed, and the conductive pattern 30 is used as a wiring part that electrically connects the semiconductor chip 50 and an external device. Furthermore, the conductive pattern 30 can also be used as not only the electric wiring part but also a heat-releasing wiring part for releasing heat by operation of elements formed in the semiconductor chip 50 to an outside.

In contrast, conductive paste is filled in a via hole (through-hole) formed in the resin films along the thickness direction and conductive particles in the conductive paste are sintered by application of pressure and heat so that the interlayer connecting portion 40 is formed. The interlayer connecting portion 40 corresponds to a sintered body in claims. The interlayer connecting portion 40 is used as a wiring part that electrically connects the semiconductor chip 50 and the external device together with the conductive pattern 30. Moreover, the interlayer connecting portion 40 can be used as the above-described heat-releasing wiring part.

In the present embodiment, the conductive pattern 30 and the interlayer connecting portion 40 form a wiring part that electrically connects electrodes 51a, 51b of the semiconductor chip 50 and an electrode 35 for connection to the external device (hereinafter referred to as an external connection electrode 35). Furthermore, the conductive pattern 30 and the interlayer connecting portion 40, which are different from the conductive pattern 30 and the interlayer connecting portion 40 which form the above-described wiring part, form a heat-releasing wiring part that thermally connects a dummy electrode 51c of the semiconductor chip 50 and the heat releasing member 60.

Specifically, copper (Cu) foil is patterned so that the conductive pattern 30 is formed. The conductive pattern 30 includes a pad 31 that corresponds to the electrode 51a of the semiconductor chip 50, a pad 32 that corresponds to the electrode 51b of the semiconductor chip 50, a pad 33 that corresponds to the dummy electrode 51c of the semiconductor chip 50, and a lateral wiring part 34 that extends in the perpendicular direction. Furthermore, the conductive pattern 30 includes the external connection electrode 35 used for connection to the external device as a part of the conductive pattern 30.

Each of the pads 31 to 33 is arranged to be adapted to pitch of the corresponding electrode 51 of the semiconductor chip 50. Although not shown, in the present embodiment, the electrode 51a is formed such that multiple electrodes 51a are arranged in a shape of a uniserial rectangular ring with ten electrodes 51a arranged in one side of the rectangular ring. The pad 31 that corresponds to the electrode 51a is formed such that multiple pads 31 are arranged in the shape of the rectangular ring in accordance with the arrangement of the electrodes 51a, as shown in FIG. 4. As shown in FIG. 1, each of the pads 31 is extracted (for rewiring) from the rectangular ring to an outside or an inside (outside in FIG. 1) thereof by the lateral wiring part 34 arranged in the same layer, and is connected to the interlayer connecting portion 40. In addition, the lateral wiring part 34 is not shown in FIG. 4 for the sake of convenience.

In the present embodiment, the interlayer connecting portion 40 is made of Ag—Sn alloy. The interlayer connecting portion 40 includes an interlayer connecting portion 41 that configures a vertical wiring part in the wiring part, and an interlayer connecting portion 42 that thermally connects the dummy electrode 51c and the heat releasing member 60.

The wiring part is configured by the interlayer connecting portion 41, the lateral wiring part 34, and the pads 31, 32. The heat-releasing wiring part is configured by the interlayer connecting portion 42 and the pad 33.

A metal diffused layer (Cu—Sn alloy layer), in which Cu and Sn are alternately diffused, is formed in an interface between the conductive pattern 30 made of Cu and the interlayer connecting portion 40 made of Ag—Sn alloy, and thereby connection reliability of the conductive pattern 30 and the interlayer connecting portion 40 is improved.

Furthermore, a metal diffused layer (Cu—Au alloy layer including CuAu₃), in which Cu and Au are alternately diffused, is formed in an interface between the pad 31 as the conductive pattern 30 made of Cu and a connecting portion 52, which is arranged on the electrode 51a of the semiconductor chip 50 and is made of Au, and thereby connection reliability of the pad 31 and the connecting portion 52 is improved.

In the present embodiment, the external connection electrode 35 as the conductive pattern 30 is formed on an inner surface of the thermosetting resin films 21a which forms a surface layer of the insulating substrate 20 at the side of the surface 20a.

The semiconductor chip 50 is an IC chip (bare chip) in which a circuit (large-scale integrated circuit) is formed. The circuit is formed by accumulating elements such as a transistor, a diode, a resistor and a capacitor on a semiconductor substrate such as silicon. The electrode 51 for connection to the external device is formed on a surface of the semiconductor chip 50. The electrode 51 includes at least an electrode to which the above-described wiring part is connected. The semiconductor chip 50 is sealed with the above-described insulating substrate 20.

In the present embodiment, as shown in FIG. 1 the electrodes 51a, 51b, which are electrically connected to the circuit, and the dummy electrode 51c, which is not connected to the circuit and does not provide an electrically connecting function, are formed.

The multiple electrodes 51a are formed on one surface of the semiconductor chip 50, and multiple connecting portions 52 made of Au are connected to the respective electrodes 51a. An extending portion in the electrode 51a, which extends in the thickness direction to the one surface of the semiconductor chip 50 from a portion opposed to the connecting portion 52, is made of Au—Al alloy (mainly made of Au₄Al alloy) and does not include Al as a simple substance of metal. In other words, the extending portion is an extending portion in the electrode 51a, which extends in the thickness direction to the one surface of the semiconductor chip 50 from a portion just below (or just above) the connecting portion 52 (i.e., a portion including an interface between the electrode 51a and the connecting portion 52 and an extending portion in the electrode 51a, which extends in the thickness direction to the one surface of the semiconductor chip 50 from the interface). Alternatively, the extending portion is a portion in the electrode 51a, which is located between the semiconductor chip 50 and the connecting portion 52. The extending portion is hereinafter referred to as a portion in the electrode 51a, which is located just below the connecting portion 52 made of Au.

The other portion in the electrode 51a, which is not located just below the connecting portion 52, (e.g., a portion covered by a protection film) includes Al as a simple substance of metal.

If Al as a simple substance remains in the portion in the electrode 51a, which is located just below the connecting portion 52 made of Au, in a high-temperature usage environment, Au in the adjacent connecting portion 52 is solid-phase diffused into Al in the electrode 51a to form Au₅Al₂. Since a growth rate of Au₅Al₂ is dramatically higher than that of Au₄Al, the diffusion of Au cannot catch up with the generation of Au₅Al₂, and thereby Kirkendall void is formed in the interface between the electrode 51a and the connecting portion 52. Furthermore, crack formation occurs from the Kirkendall void as a starting point.

In contrast, in the present embodiment, the portion in the electrode 51a, which is located just below the connecting portion 52 made of Au, does not include Al as a simple substance of metal, and mainly includes Au₄Al alloy as a finished product of Au—Al alloy. Therefore, in the high-temperature usage environment, the formation of the Kirkendall void, therefore, the crack can be restrained.

A pitch (distance) between the adjacent electrodes 51a is smaller than that between the electrodes 51b, 51c formed on a surface of the semiconductor chip 50, which is opposite from the one surface thereof (hereinafter referred to as an opposite surface of the semiconductor chip 50). Specifically, the pitch is tens of μm (for example, 60 μm).

In contrast, the electrode 51b and the dummy electrode 51c, which are made of Ni material, are formed on the opposite surface of a formation surface of the electrode 51 (hereinafter referred to as an electrode formation surface) of the semiconductor chip 50. The interlayer connecting portions 41, 42 as connecting portions with the corresponding pads 32, 33 are connected to the electrodes 51b, 51c, respectively. A metal diffused layer (Ni—Sn alloy layer), in which Sn and Ni are alternately diffused, is formed in each of interfaces between the electrodes 51b, 51c made of Ni and corresponding interlayer connecting portions 41, 42, and thereby connection reliability of the electrodes 51b, 51c and the interlayer connecting portion 40 is improved. In addition, a pitch of the electrodes 51b, 51c is, for example, hundreds of μm.

In this manner, the semiconductor chip 50 has the electrodes 51a, 51b, which provide an electrically connecting function, and the dummy electrode 51c, which does not provide an electrically connecting function, formed on both surfaces thereof. The elements of the semiconductor chip 50 include, an element, in which current flows in the thickness direction, such as a vertical MOSFET, a vertical IGBT and a vertical resistor. Thus, the electrodes 51a, 51b are formed on both surfaces of the semiconductor chip 50.

The heat releasing member 60 is made of metal material such as Cu, and is used for releasing heat by operation of the elements formed in the semiconductor chip 50 to the outside. As the heat releasing member 60, a heat sink, a heat releasing fin or the like can be used.

In the present embodiment, the tabular heat releasing member 60, which is made of Cu and has the size and shape generally corresponding to those of the other surface 20b of the insulating substrate 20, is used. The thermoplastic resin film 22d is bonded firmly to the heat releasing member 60 so that the heat releasing member 60 is fixed to the surface 20b of the insulating substrate 20.

One end of the interlayer connecting portion 42 formed in the thermoplastic resin film 22d is connected to the heat releasing member 60. In the present embodiment, a metal diffused layer (Cu—Sn alloy layer), in which Cu and Sn are alternately diffused, is formed in an interface between the heat releasing member 60 made of Cu and the interlayer connecting portion 42 made of Ag—Sn alloy, and thereby connection reliability of the heat releasing member 60 and the interlayer connecting portion 42 (i.e., the heat-releasing wiring part) is improved.

In the present embodiment, heat generated in the semiconductor chip 50 is transferred to the heat releasing member 60 from the dummy electrode 51c through the heat-releasing wiring part configured by the interlayer connecting portion 42 and the pad 33. Therefore, a heat releasing property is improved.

Furthermore, the insulating substrate 20 has a hole at the side of the surface 20a. The external connection electrode 35 serves as the bottom surface of the hole. A conductive member such as a plating film is arranged in the hole and a solder ball 70 is formed on the conductive member.

Accordingly, in the present embodiment, the semiconductor chip 50 has the electrodes 51a, 51b, which provide the electrically connecting function, on both surfaces thereof. In contrast, the heat releasing member 60 is arranged on the surface 20b of the insulating substrate 20 and the external connection electrode 35 is arranged only on the surface 20a of the insulating substrate 20. That is, although the semiconductor chip 50 has a double-sided electrode structure, the wiring substrate 10 has a one-sided electrode structure.

Next, a manufacturing method of the above-described wiring substrate 10 will be described. In addition, the reference numeral in parentheses behind the reference numeral 40a, which denotes the conductive paste denotes the corresponding interlayer connecting portion.

First, components constituting a stacked body are prepared so as to form the wiring substrate 10 by application of pressure and heat to the stacked body. A substrate on which the semiconductor chip 50 is mounted (hereinafter referred to as a semiconductor unit 80) and the multiple resin films to be stacked on the semiconductor unit 80 are prepared.

In the present embodiment, as described above, a film made of thermosetting polyimide (PI), which does not include inorganic material such as glass fiber, is used as the thermosetting resin films 21a to 21d. In the present embodiment, for example, all the resin films 21a to 21d are the same in thickness (e.g., 50 μm).

In contrast, a resin film made of 30 weight percent of polyether ether ketone (PEEK) and 70 weight percent of polyetherimide (PEI), which does not include inorganic material such as glass fiber and inorganic filler for adjusting a linear expansion coefficient, is used as the thermoplastic resin films 22a to 22d. In the present embodiment, for example, the resin films 22a, 22c, 22d are the same in thickness (e.g., 80 μm), and the thermoplastic resin film 22b as the second film is smaller than the resin films 22a, 22c, 22d in thickness (e.g., 50 μm).

In the preparing process, as is well known by a lump-sum stacking method known as PALAP, with respect to the resin films constituting the insulating substrate 20, the conductive pattern 30 is formed and the conductive paste 40a, which becomes the interlayer connecting portion 40 by sintering, is filled in the via hole before the lump-sum stacking. The arrangement of the conductive pattern 30 and the via hole, in which the conductive paste 40a is filled, is arbitrarily determined in accordance with the wiring part or the heat-releasing wiring part.

The conductive foil attached to the surface of the resin film is patterned so that the conductive pattern 30 is formed. As long as the multiple resin films constituting the insulating substrate 20 include the resin film having the conductive pattern 30, a configuration in which all the resin films have the conductive patterns 30, respectively, or a configuration in which a part of the resin films does not have the conductive pattern 30 can be applied, for example. In addition, as the resin film having the conductive pattern 30, a resin film having the conductive pattern 30 on one surface thereof and a resin film having the conductive patterns 30 on both surfaces thereof in the stacking direction can be applied.

Ethylcellulose resin, acrylic resin or the like is added to the conductive particles so as to maintain the shape of the conductive paste 40a and the conductive particles are mixed and kneaded in organic solvent such as terpineol so that the conductive paste 40a can be obtained. The via hole that penetrates the resin film is formed by carbon dioxide laser or the like, and the conductive paste 40a is filled in the via hole by screen printing or the like. The via hole may be formed with the conductive pattern 30 used as the bottom surface thereof or the via hole may be formed in a position where the conductive pattern 30 is not arranged.

In the case where the via hole is formed on the conductive pattern 30, since the conductive pattern 30 serves as the bottom of the via hole, the conductive paste 40a can remain in the via hole. In contrast, in the case where the via hole is formed in the resin film without the conductive pattern 30 or in the case where while the resin film has the conductive pattern 30, the via hole is formed in a position different from the conductive pattern 30, the conductive paste 40a described in Japanese Patent Application No. 2008-296074 by the present applicant is used such that the conductive paste 40a remains in the via hole without a bottom. In addition, a device (method) described in Japanese Patent Application No. 2009-75034 by the present applicant may be used as a device (method) for filling a via hole with the conductive paste 40a.

A low-melting-point solid resin, which is solid at room temperature, is added to the conductive paste 40a. The low-melting-point solid resin decomposes and vaporizes at a temperature lower than a sintering temperature of the conductive particles. The low-melting-point solid resin is in a melting state at a temperature lower than the temperature and higher than the room temperature, and is solid at the room temperature. An example of the low-melting-point solid resin is paraffin. By heating the low-melting-point solid resin when filling the via hole, the low-melting-point solid resin is melted to be in a paste form. By cooling the low-melting-point solid resin after filling the via hole, the low-melting-point solid resin is solidified so that the conductive paste 40a is solidified and can remain in the via hole. In addition, when filling the via hole one end of the via hole is closed by a flat member.

First, the process for preparing six resin films 21a, 21c, 21d, 22a, 22c, 22d which are stacked on the semiconductor unit 80 will be described.

In the present embodiment, as shown in FIG. 2, a film, to one surface of which the copper foil (e.g., thickness of 18 μm) is attached, is prepared for each of the thermosetting resin films 21a, 21c, 21d in the six resin films. The respective copper foils are patterned to form the conductive patterns 30. In addition, a film, to one surface of which the copper foil (likewise thickness of 18 μm) is attached, is prepared for the thermosetting resin film 21b in the other two resin films 21b, 22b. The copper foil is patterned to form the conductive pattern 30.

That is, each of the thermosetting resin films 21a to 21d has the conductive pattern 30 on one surface thereof, and each of the thermoplastic resin films 22a to 22d does not have the conductive pattern 30.

Via holes (reference numerals are omitted) are formed in five resin films 21c, 21d, 22a, 22c, 22d in the six resin films other than the thermosetting resin film 21a, which has the external connection electrode 35 on one surface thereof (inner surface in the stacked state) as the conductive pattern 30 and configures the surface layer of the insulating substrate 20 at the side of the surface 20a. The via holes are filled with the conductive paste 40a. After filling the via holes, the solvent is vaporized by a drying process.

In the present embodiment, the conductive patterns 30 are formed only on the thermosetting resin films 21a, 21c, 21d. Thus, with respect to the thermoplastic resin films 22a, 22c, 22d without the conductive patterns 30, the conductive paste 40a, which includes Ag particles and Sn particles as the conductive particles at a predetermined rate and to which the above-described low-melting-point solid resin such as paraffin is added, is used.

With respect to the thermosetting resin films 21c, 21d, the conductive paste 40a which is the same as that used in the thermoplastic resin films 22a, 22c, 22d may be used. Alternatively, the conductive paste 40a which includes Ag particles and Sn particles as the conductive particles at a predetermined rate and does not include the low-melting-point solid resin may be used.

Furthermore, since the stacked body has a cavity for housing the semiconductor chip 50, a cavity portion is formed in a part of the multiple resin films in advance in the preparing process. In the present embodiment, a cavity portion 23 for housing the semiconductor chip 50 is formed in the thermosetting resin film 21c. Thus, the thermosetting resin film 21c having the cavity portion 23 has a rectangular frame shape.

The cavity portion 23 can be formed by a mechanical process such as a punch or a drill, or irradiation of a laser beam, and is formed to have a predetermined margin with respect to the size of the semiconductor chip 50. The cavity portion 23 may be formed before or after forming the conductive pattern 30 and the interlayer connecting portion 40.

Moreover, a forming process of the semiconductor unit 80 is performed in parallel with the preparing process of the above-described resin films 21a, 21c, 21d, 22a, 22c, 22d.

First, a resin film including at least the first film and constituting a substrate on which the semiconductor chip 50 is mounted, and the second film that seals between the substrate and the semiconductor chip 50 are prepared.

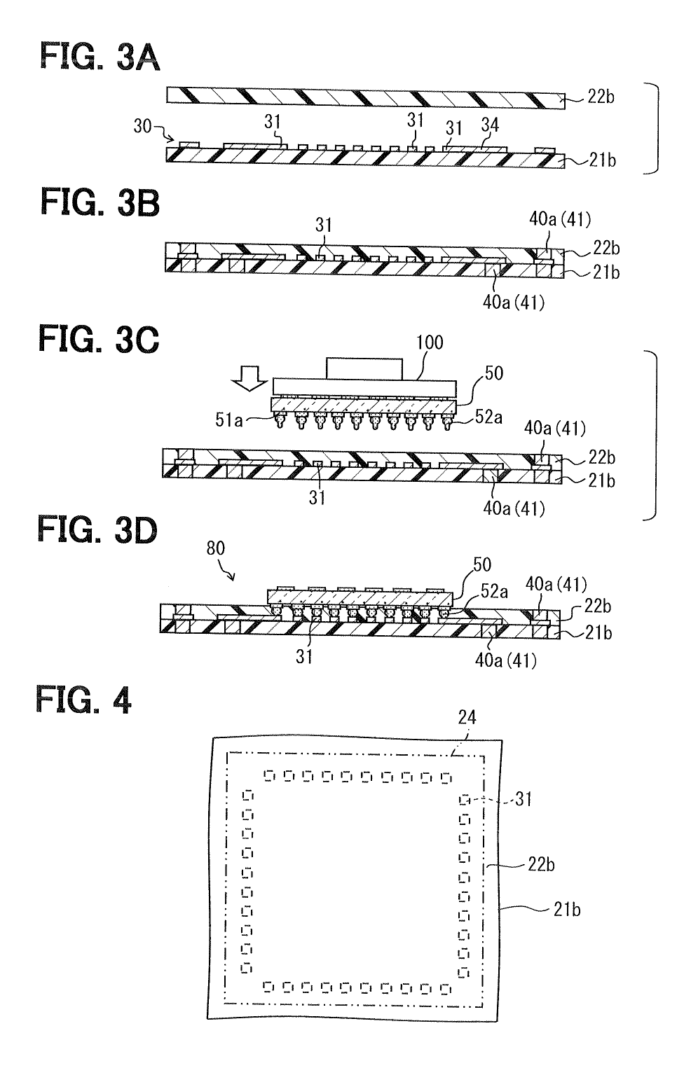

In the present embodiment, as shown in FIG. 3A, the thermosetting resin film 21b as the first film constituting the substrate, and the thermoplastic resin film 22b as the second film are prepared. The thermosetting resin film 21b, to one surface of which the copper foil is attached is prepared, and the copper foil is patterned to form the conductive pattern 30. At this time, the pad 31 is also formed as the conductive pattern 30.

Subsequently, the thermoplastic resin film 22b is attached to a surface of the substrate, on which the pad is formed, (i.e., pad formation surface) to cover the pad 31 by application of pressure and heat.

In the present embodiment, as shown in FIGS. 3B and 4, the thermoplastic resin film 22b is thermal compression bonded to the pad formation surface of the thermosetting resin film 21b as the substrate to cover the pad 31. In addition, the region shown by the two-dot chain line in FIG. 4 indicates a mounting region 24 of the semiconductor chip 50.

Specifically, the thermoplastic resin film 22b is pressurized toward the thermosetting resin film 21b while heating such that a temperature of the thermoplastic resin film 22b becomes equal to or higher than a glass-transition temperature and equal to or lower than a melting point of the thermoplastic resin constituting the film 22b. Thus, the softened thermoplastic resin is bonded firmly to a land formation surface of the thermosetting resin film 21b and a surface of the conductive pattern 30.

After the thermoplastic resin film 22b is thermal compression bonded to the thermosetting resin film 21b, the via holes are formed in the resin films 21b, 22b with the conductive patterns 30 used as the bottom surfaces of the respective via holes, and the via holes are filled with the conductive paste 40a, as shown in FIG. 3B. Here, since the conductive pattern 30 serves as the bottom surface of the via hole, as the conductive paste 40a, conductive paste which does not include the low-melting-point solid resin may be used, or conductive paste which includes the low-melting-point solid resin may be used.

Next, the separately prepared semiconductor chip 50 is flip-chip mounted on the substrate.

The semiconductor chip 50 has a stud bump 52a on the electrode 51a, which is formed on a mounting surface with respect to the substrate. In the present embodiment, the stud bump 52a (stud-shaped bump) made of Au, which is formed by a well-known method with the use of a wire, for example, is formed on the electrode 51a made of Al material.

Then, as shown in FIG. 3C, the semiconductor chip 50 is pressurized toward the substrate while heating the semiconductor chip 50 from a side of a rear surface of the mounting surface by a pulse-heating type thermal compression tool 100, for example. At this time, the semiconductor chip 50 is pressurized toward the thermosetting resin film 21b while heating the semiconductor chip 50 at a temperature equal to or higher than the melting point (330° C. when PEEK:PEI=30:70) of the thermoplastic resin constituting the thermoplastic resin film 22b.

When the heat from the thermal compression tool 100 is transferred to the semiconductor chip 50 and a temperature of a tip end of the stud bump 52a becomes equal to or higher than the melting point of the thermoplastic resin constituting the thermoplastic resin film 22b, a portion of the thermoplastic resin film 22b the stud bump 52a contacts is softened and melted. Therefore, while melting the thermoplastic resin film 22b, the stud bump 52a is stuffed into the thermoplastic resin film 22b and can contact the corresponding pad 31. Accordingly, as shown in FIG. 3D, the stud bump 52a and the pad 31 can be in a pressure welding state.

Furthermore, the melted and softened thermoplastic resin flows by application of pressure to adhere to the mounting surface of the semiconductor chip 50, the pad formation surface of the thermosetting resin film 21b, the conductive pattern 30, the electrode 51a and the stud bump 52a. Therefore, as shown in FIG. 3D, the thermoplastic resin film 22b can seal between the semiconductor chip 50 and the thermosetting resin film 21b (substrate). Thus, the semiconductor unit 80 is formed.

In the present embodiment, in flip-chip mounting, the heating temperature is set to be about 350° C. slightly higher than the melting point, and the pressure is applied such that a load on one stud bump 52a becomes about 20 to 50 gf. Accordingly, the stud bump 52a and the pad 31 can be in the pressure welding state in a short time.

After being in the pressure welding state, by continuing the application of heat and pressure, Au constituting the stud bump 52a and Cu constituting the pad 31 are alternately diffused (solid-phase diffusion) to form a metal diffused layer (Cu—Au alloy layer). Moreover, Au constituting the stud bump 52a is solid-phase diffused into Al constituting the electrode 51a to form a metal diffused layer (Au—Al alloy layer). However, in order to form such a metal diffused layer, compared with the formation of the above-described pressure welding state, a long time is required as heating and pressurizing time. If a long time is required to mount the one semiconductor chip 50 on the substrate, the time to form the wiring substrate 10 in which the semiconductor chip 50 is embedded may become long as a result, and thereby increasing a manufacturing cost. Furthermore, unnecessary heat may be applied to parts other than the electrically connecting portions of the electrode 51a, the stud bump 52a and the pad 31 in the meantime. For this reason, in the mounting process, the connection state between the stud bump 52a and the pad 31 is held to the pressure welding state.

In the present embodiment, after attaching the thermoplastic resin film 22b to the thermosetting resin film 21b, the via holes are formed and filled with the conductive paste 40a. However, before attaching the thermoplastic resin film 22b to the thermosetting resin film 21b, the via holes may be formed in the respective resin films 21b, 22b and filled with the conductive paste 40a.

The conductive particles of the conductive paste 40a may be sintered to form the interlayer connecting portion 40 (41) due to the application of heat and pressure when the semiconductor chip 50 is flip-chip mounted on the substrate, or the application of heat and pressure when attaching the thermoplastic resin film 22b to the thermosetting resin film 21b in the case where the via hole is filled with the conductive paste 40a before the attaching. The conductive particles may not be sintered and the conductive paste 40a may maintain the paste form at the time when the semiconductor unit 80 is formed. Alternatively, a part of the conductive paste 40a may be sintered. In the present embodiment the conductive paste 40a is in the paste form after the flip-chip mounting.

Next, a stacking process for forming the stacked body is performed. In the process, the multiple resin films including the resin film, on the surface of which the conductive pattern 30 is formed, and the resin film having the via hole filled with the conductive paste 40a are stacked such that the thermoplastic resin films are arranged at least every other film and contact the electrode formation surface and the opposite surface of the electrode formation surface of the semiconductor chip 50.

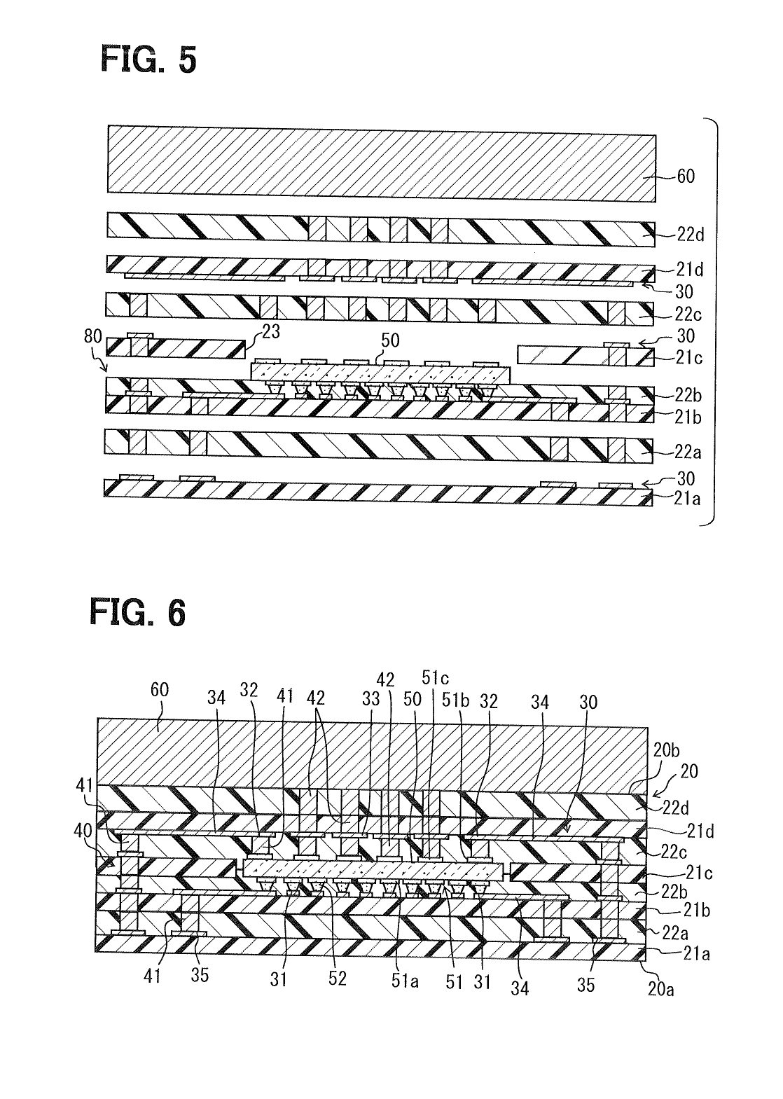

In the present embodiment, as shown in FIG. 5, the multiple resin films 21a, 21c, 21d, 22a, 22c, 22d and the semiconductor unit 80 are stacked such that the thermosetting resin film 21a, the thermoplastic resin film 22a, the thermosetting resin film 21b, the thermoplastic resin film 22b, the thermosetting resin film 21c, the thermoplastic resin film 22c, the thermosetting resin film 21d and the thermoplastic resin film 22d are arranged in this order from the one side in the stacking direction. Thus, in the present embodiment, the thermoplastic resin films 22a to 22d and the thermosetting resin films 21a to 21d are stacked alternately.

Furthermore, the heat releasing member 60 is stacked on the thermoplastic resin film 22d. In addition, in FIG. 5, the components constituting the stacked body are located separately from each other for the sake of convenience.

Specifically, the thermoplastic resin film 22a is stacked on a conductive pattern formation surface of the thermosetting resin film 21a, and the semiconductor unit 80 is stacked on the thermoplastic resin film 22a with the thermosetting resin film 21b served as a mounting surface. The thermosetting resin film 21c is stacked on the thermoplastic resin film 22b around the semiconductor chip 50 in the semiconductor unit 80 with the thermosetting resin film 21c served as a mounting surface. The thermoplastic resin film 22c is stacked on the thermosetting resin film 21c and the semiconductor chip 50, and the thermosetting resin film 21d is stacked on the thermoplastic resin film 22c with a conductive pattern formation surface of the thermosetting resin film 21d served as a mounting surface. The thermoplastic resin film 22d is stacked on the thermosetting resin film 21d and the heat releasing member 60 is stacked on the thermoplastic resin film 22d so that one stacked body is formed.

In the stacked body, the semiconductor chip 50 is adjacent to the thermoplastic resin films 22b, 22c in the stacking direction. At least the thermoplastic resin films 22b, 22c function to seal the periphery of the semiconductor chip 50 in the pressurizing and heating process. In the present embodiment, the thermosetting resin film 21c surrounds the semiconductor chip 50 in the perpendicular direction, and thus, the above-described two resin films 22b, 22c function to seal the periphery of the semiconductor chip 50.

In this manner, it is preferable that a thermoplastic resin film, which does not include inorganic material such as glass fiber and aramid fiber and inorganic filler for adjusting a linear expansion coefficient and a melting point, is used as the thermoplastic resin films 22b, 22c for sealing the semiconductor chip 50. Therefore, stress can be restrained from being locally applied on the semiconductor chip 50 in the pressurizing and heating process.

However, if the thermoplastic resin films 22b, 22c, which do not include inorganic filler for adjusting a linear expansion coefficient and a melting point, are used, a linear expansion coefficient difference with the semiconductor chip 50 may become large because the resin films do not include inorganic filler. Thus, stress may be increased. In order to decrease the stress, it is preferable that a resin film having a low elastic modulus (e.g., equal to or lower than 10 GPa) is used as the thermoplastic resin films 22b, 22c.

Furthermore, it is preferable that a resin film having a thickness of equal to or larger than 5 μm is used as the thermoplastic resin films 22b, 22c for sealing the semiconductor chip 50. This is because, if the thickness is smaller than 5 μm the stress applied on the resin films 22b, 22c is increased and the resin films 22b, 22c may be peeled from the surface of the semiconductor chip 50 in the pressurizing and heating process.

Subsequently, the pressurizing and heating process in which the stacked body is heated and pressurized from upper and lower sides in the stacking direction by using a vacuum heat pressing machine is performed. In the process, by softening thermoplastic resin, the multiple resin films are integrated at one time and the semiconductor chip 50 is sealed. Furthermore the conductive particles in the conductive paste 40a are sintered to form the sintered body, and a wiring part including the sintered body and the conductive pattern 30 is formed.

In the pressurizing and heating process, the resin films are integrated at one time to form the insulating substrate 20, and held during predetermined time under a temperature equal to or higher than the glass-transition temperature and equal to or lower than the melting point of thermoplastic resin constituting the resin films and a pressure of several MPa to form the sintered body from the conductive particles in the conductive paste 40a. In the present embodiment, the resin films are held under the pressing temperature of 280° C. to 330° C. and the pressure of 4 to 5 MPa for 5 minutes or more (for example, 10 minutes).

First, a connection between the resin films in the pressurizing and heating process will be described.

The thermoplastic resin films 22a to 22d arranged every other film are softened by the above-described heating. Since the multiple resin films are pressurized at this time, the softened thermoplastic resin films 22a to 22d adhere to the adjacent thermosetting resin films 21a to 21d, respectively. Thus, the multiple resin films 21a to 21d, 22a to 22d are integrated at one time so that the insulating substrate 20 is formed. At this time, the thermoplastic resin film 22d adheres to the adjacent heat releasing member 60 so that the heat releasing member 60 is integrated with the insulating substrate 20.

Moreover, the thermoplastic resin films 22b, 22c which are adjacent to the semiconductor chip 50 flow by application of the pressure to adhere to the formation surface of the electrode 51a of the semiconductor chip 50 and the formation surface of the electrodes 51b, 51c, which is opposite from the formation surface of the electrode 51a. Furthermore, the thermoplastic resin films 22b, 22c flow into a space between a side surface of the semiconductor chip 50 and the thermosetting resin film 21c to fill the space and adhere to the side surface of the semiconductor chip 50. Therefore, the semiconductor chip 50 is sealed with thermoplastic resin (the thermoplastic resin films 22b, 22c).

Next, a connection of the electrode 51 of the semiconductor chip 50, the conductive pattern 30 and the interlayer connecting portion 40 in the pressurizing and heating process will be described.

By the above-described heating, Sn (melting point of 232° C.) in the conductive paste 40a is melted to be diffused into Ag particles in the conductive paste 40a so that Ag—Sn alloy (melting point of 480° C.) is formed. Moreover, since the pressure is applied to the conductive paste 40a, the interlayer connecting portion 40 (41, 42) made of the integrated alloy by sintering is formed in the via hole.

Melted Sn is alternately diffused with Cu constituting the conductive pattern 30 (the pads 31 to 33). Thus, the metal diffused layer (Cu—Sn alloy layer) is formed in the interface between the interlayer connecting portion 40 and the conductive pattern 30.

Melted Sn is alternately diffused with Ni constituting the electrodes 51b, 51c of the semiconductor chip 50. Thus, the metal diffused layer (Ni—Sn alloy layer) is formed in the interface between the interlayer connecting portion 40 and the electrodes 51b, 51c.

Moreover, Au constituting the stud bump 52a is solid-phase diffused into Al constituting the electrode 51a of the semiconductor chip 50. Since the electrode 51a is an electrode for fine pitch, the amount of Al constituting the electrode 51a is small compared with the amount of Au constituting the stud bump 52a. Thus, Al included in the extending portion in the electrode 51a, which extends in the thickness direction to the semiconductor chip 50 from the portion opposed to the connecting portion 52, is used for alloying with Au, and the extending portion does not include Al as a simple substance of metal after the pressurizing and heating process. The electrode 51a after the pressurizing and heating process mainly includes Au₄Al alloy as Au—Al alloy.

Even if Au₅Al₂ having a rapid growth rate is formed before forming Au₄Al alloy in the pressurizing and heating process, the formation of the Kirkendall void can be restrained because the pressure is applied.

Furthermore, Au constituting the stud bump 52a is alternately diffused with Cu constituting the conductive pattern 30 (the pad 31). Therefore, a Cu—Au alloy layer which includes CuAu₃ alloy is formed in'an interface between the connecting portion 52 formed from the stud bump 52a and the pad 31. Cu—Au alloy can be formed with heat of a temperature equal to or higher than about 250° C., and the Cu—Au alloy layer can be formed under the above-described pressurizing and heating condition.

The rest of Au used for the solid-phase diffusion bonding in the stud bump 52a serves as the connecting portion 52 that electrically connects the electrode 51a including the portion made of Au—Al alloy with the pad 31, which has the Cu—Au alloy layer in the interface thereof and is made of Cu. In this manner, in the pressurizing and heating process, the connection state between the stud bump 52a and the pad 31 becomes a directly bonding state.

Accordingly, as shown in FIG. 6, a substrate, in which the semiconductor chip 50 is embedded in the insulating substrate 20, the semiconductor chip 50 is sealed with thermoplastic resin, the semiconductor chip 50 is electrically connected to the external connection electrode 35 by the wiring part, and the semiconductor chip 50 is thermally connected to the heat releasing member 60 by the heat-releasing wiring part, can be obtained.

Then, in the substrate, a hole with the external connection electrode 35 used as the bottom surface is formed from the side of the surface 20a of the insulating substrate 20, and a conductive member such as a plating film is arranged in the hole. After that, the solder ball 70 is formed on the conductive member so that the wiring substrate 10 shown in FIG. 1 can be obtained.

Next, effects of characterizing portions in the wiring substrate 10 and the manufacturing method thereof, which are described in the present embodiment, will be described. First, effects of main characterizing portions will be described.

In the present embodiment, in forming the wiring substrate 10, the multiple resin films 21a to 21d, 22a to 22d are stacked such that the thermoplastic resin films 22a to 22d are arranged at least every other film and contact the formation surface of the electrode 51a and the opposite surface of the formation surface of the semiconductor chip 50 to form the stacked body.

Therefore, the multiple resin films 21a to 21d, 22a to 22d can be integrated at one time by application of pressure and heat with the use of thermoplastic resin constituting the thermoplastic resin films 22a to 22d as adhesive. The semiconductor chip 50 can be sealed with at least the thermoplastic resin films 22b; 22c which are adjacent to the semiconductor chip 50. Furthermore, the wiring part can be formed by the sintered body, which is formed from the conductive particles in the conductive paste 40a by the above-described application of pressure and heat, together with the conductive pattern 30. Thus, a manufacturing process of the wiring substrate 10 can be simplified.

Moreover, before the stacking process for forming the stacked body, the thermoplastic resin film 22b is arranged between the semiconductor chip 50 and the substrate (the thermosetting resin film 21b), and is heated and pressurized at a temperature equal to or higher than the melting point of thermoplastic resin. While the temperature is increased to be equal to or higher than the melting point of thermoplastic resin, thermoplastic resin has fluidity, the thermoplastic resin located between the stud bump 52a and the pad 31 moves by application of pressure, and the stud bump 52a directly contacts the pad 31 so that the stud bump 52a and the pad 31 can be in the pressure welding state.

At this time, the melted thermoplastic resin flows by application of pressure to seal between the semiconductor chip 50 and the substrate (the thermosetting resin film 21b) including the periphery of a connecting portion of the stud bump 52a and the pad 31. Therefore, an electrically insulating property between the respective connecting portions can be obtained. Moreover, the connection reliability at the connecting portion can be improved.

Moreover, when the stud bump 52a and the pad 31 are in the pressure welding state, the flip-chip mounting process (application of heat and pressure) is terminated, and the stud bump 52a and the pad 31 are in the bonding state by the application of pressure and heat in the pressurizing and heating process. Since the stud bump 52a (the connecting portion 52) and the pad 31 are in the bonding state by using the heat and pressure of the pressurizing and heating process, compared with the pressure welding state, the electrically connection reliability of the electrode 51a of the semiconductor chip 50 and the pad 31 can be improved.

In the flip-chip mounting process, the stud bump 52a and the pad 31 are in the pressure welding state, and then, by using the heat and pressure of the pressurizing and heating process, the stud bump 52a and the pad 31 are in the bonding state. Thus, manufacturing time can be shortened compared with a method in which the pressurizing and heating process is performed after the stud bump 52a and the pad 31 are in the bonding state in the flip-chip mounting process.

If the stud bump 52a is not brought into contact with the pad 31 before the stacking process and the stud bump 52a is brought into contact with the pad 31 to be in the bonding state in the pressurizing and heating process, it becomes difficult for the stud bump 52a to be stuffed into the thermoplastic resin film 22b as the second film because of a cushioning effect of the softened thermoplastic resin. Thus, the thermoplastic resin may remain between the stud bump 52a and the pad 31.

In contrast, since the stud bump 52a and the pad 31 are in the pressure welding state before the stacking process in the present embodiment, the stud bump 52a and the pad 31 can reliably be in the bonding state by using the heat and pressure of the pressurizing and heating process.

Therefore, according to the manufacturing method of the present embodiment, the manufacturing process of the wiring substrate 10 can be simplified and the manufacturing time (cycle time) can be shortened.

Next, effects of other characterizing portions will be described.

In the present embodiment the conductive patterns 30 are formed on only the thermosetting resin films 21a to 21d, and the conductive patterns 30 are not formed on the thermoplastic resin films 22a to 22d. Thus, if the thermoplastic resin is softened in the pressurizing and heating process or the like and flows by the application of pressure, since the conductive patterns 30 are fixed to the respective thermosetting resin films 21a to 21d, positional deviations of the conductive patterns 30 can be restrained. Therefore, the configuration is preferable for the wiring substrate 10 (semiconductor device) in which the semiconductor chip 50 for fine pitch is embedded.

Furthermore, in the present embodiment, Au constituting the stud bump 52a is solid-phase diffused into Al constituting the electrode 51a that contacts one end of the stud bump 52a, and is solid-phase diffused into Cu constituting the pad 31 that contacts the other end of the stud bump 52a in the pressurizing and heating process. Therefore, the electrically connection reliability of the electrode 51a and the pad 31 through the stud bump 52a (the connecting portion 52) can be further improved, and the manufacturing process can be simplified by forming Au—Al alloy and Cu—Au alloy in the same process.

In the semiconductor chip 50 having the electrodes 51 on both surfaces thereof, if the solid-phase diffusion bonding is performed with respect to the electrodes 51 formed on the both surfaces, solid materials contact the both surfaces of the semiconductor chip 50 during the pressurizing and heating process, and thereby the pressure (press pressure) applied to the semiconductor chip 50 may be increased. In contrast, in the present embodiment, the electrode 51a is electrically connected to the pad 31 by the solid-phase diffusion of Au at the one surface side of the semiconductor chip 50, and the electrodes 51b, 51c are electrically connected to the pads 32, 33, respectively, by the liquid-phase diffusion of melted Sn at the opposite surface side of the semiconductor chip 50. Thus, the pressure applied to the semiconductor chip 50 can be buffered at the liquid-phase side. Therefore, although the electrode 51 at one side corresponds to the fine pitch, which is formed by the solid-phase diffusion with the use of the stud bump 52a, the pressure applied to the semiconductor chip 50 in the pressurizing and heating process can be decreased and the reliability of the semiconductor chip 50 can be increased.

Moreover, in the present embodiment, a resin film, which does not include inorganic material such as glass fiber and inorganic filler, is used as the thermoplastic resin films 22b, 22c. Thus, the pressure applied to the semiconductor chip 50 in the pressurizing and heating process can be decreased.

Furthermore, in the present embodiment, the portion in the electrode 51a, which is located just below the stud bump 52a, does not include Al as a simple substance of metal and mainly includes Au—Al alloy by the solid-phase diffusion of Au from the stud bump 52a in the pressurizing and heating process. Thus, since the whole of portion in the electrode 51a, which contacts the connecting portion 52 made of Au, is alloyed, the formation of the Kirkendall void due to the diffusion of Au from the connecting portion 52 can be restrained even in the high-temperature usage environment.

### Second Embodiment

In the first embodiment, when the semiconductor chip 50 is flip-chip mounted on the thermosetting resin film 21b as the substrate, the stud bump 52a is stuffed into the thermoplastic resin film 22b attached to the pad formation surface of the thermosetting resin film 21b to secure the pressure welding state with the pad 31.

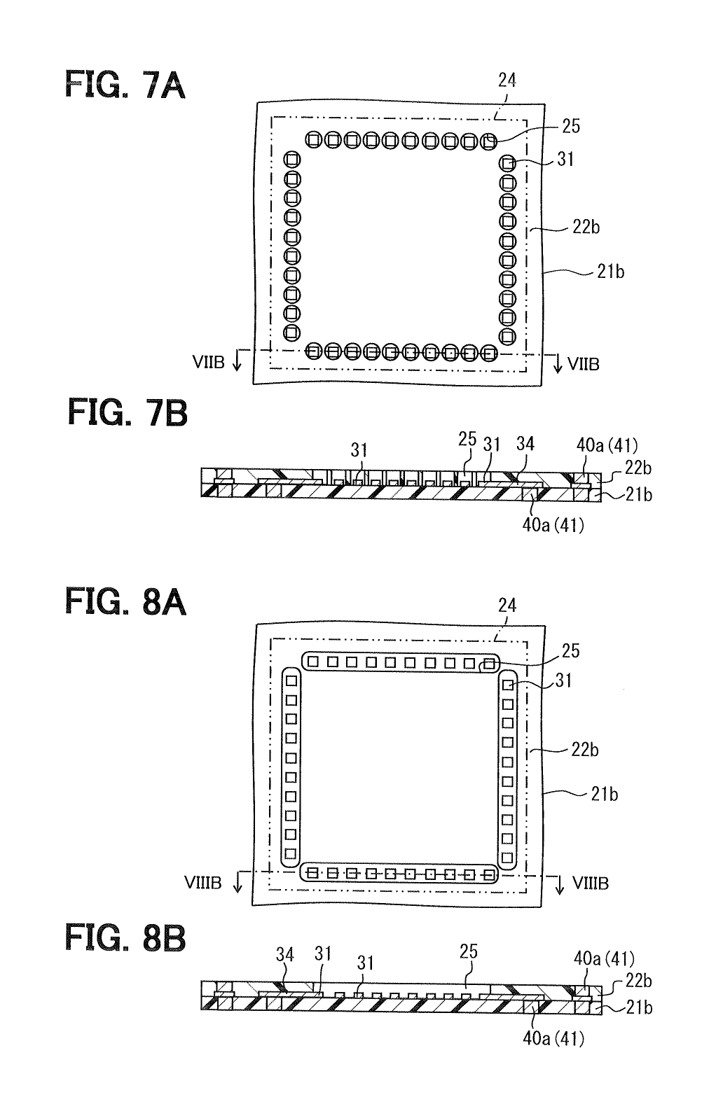

In contrast, in the present embodiment, as shown in FIGS. 7A and 7B, a through-hole 25 is formed in the thermoplastic resin film 22b at a position corresponding to the pad 31, and the thermoplastic resin film 22b is attached to the pad formation surface of the thermosetting resin film 21b such that the through-hole 25 covers the pad 31.

In the example shown in FIGS. 7A and 7B, each of the multiple through-holes 25 is formed for the corresponding one pad 31. Accordingly, since the thermoplastic resin film 22b is located between the adjacent connecting portions, each of which is formed between the stud bump 52a and the pad 31, it is easy for the softened thermoplastic resin to cover the connecting portion in the flip-chip mounting process. That is, although the through-holes 25 are formed, the electrically insulating property between the adjacent connecting portions can be obtained and the connection reliability at each of the connecting portions can be improved.

In the case where the electrodes 51a of the semiconductor chip 50 are arranged at fine pitch, the pads 31 are also arranged at fine pitch. Thus, it is difficult to form the through-hole 25 that is smaller than the pad 31 (for example, a diameter thereof is 30 μm). However, unlike the via hole (through-hole) for forming therein the interlayer connecting portion 40, the through-hole 25 is not filled with the conductive paste 40a and does not define the size of the connecting portion 52 that electrically connects the electrode 51a of the semiconductor chip 50 with the pad 31. Thus, the through-hole 25 can be formed larger than the pad 31. Therefore, a degree of freedom for the formation of the through-hole 25 is higher than that of the via hole, and the through-holes 25 can be formed for every pad 31.

The semiconductor chip 50 is flip-chip mounted on the thermosetting resin film 21b by being pressurized and heated under a temperature equal to or higher than the glass-transition temperature of the thermoplastic resin constituting the thermoplastic resin film 22b (in other words, a softening temperature at which the thermoplastic resin softens). Accordingly, the stud bump 52a of the semiconductor chip 50 is pressure welded to the corresponding pad 31 through the through-hole 25, and, the softened thermoplastic resin seals between the semiconductor chip 50 and the thermosetting resin film 21b.

By using such a method, the similar effects to the manufacturing method described in the first embodiment can be obtained.

According to the manufacturing method of the present embodiment, it is not necessary to melt the thermoplastic resin film 22b in forming the pressure welding state between the stud bump 52a and the pad 31. It is necessary for the softened thermoplastic resin to seal between the semiconductor chip 50 and the thermosetting resin film 21b by heating and pressurizing under the temperature equal to or higher than the glass-transition temperature of the thermoplastic resin constituting the thermoplastic resin film 22b. In other words, it is necessary for the semiconductor chip 50 to be thermal compression bonded to the thermoplastic resin film 22b. The through-hole 25 is formed in advance in the thermoplastic resin film 22b before the flip-chip mounting. Thus, the pressure welding state can be formed easily in the present embodiment, compared with the method described in the first embodiment.

Thus, if heat quantity is the same, the pressure welding state between the stud bump 52a and the pad 31 and the sealing structure by the thermoplastic resin film 22b can be formed in a short time, compared with the method described in the first embodiment. That is, the heating and pressurizing time in the flip-chip mounting process, therefore, the manufacturing time of the wiring substrate 10 can be shortened.

Furthermore, if the heating and pressurizing time and a pressurized condition are the same, the pressure welding state between the stud bump 52a and the pad 31 can be obtained with low heat quantity, compared with the method described in the first embodiment.

The through-hole 25 may be formed before or after attaching of the thermoplastic resin film 22b to the thermosetting resin film 21b. In the present embodiment, after the attaching, the through-hole 25 is formed in the thermoplastic resin film 22b at the position corresponding to the pad 31 by carbon dioxide laser or the like. By using such a method the through-hole 25 can be formed with a high degree of positional accuracy.

In contrast, in the case where the through-hole 25 is formed by irradiation of a laser beam or the like before the attaching, the thermoplastic resin film 22b is attached to the thermosetting resin film 21b by application of pressure while a position in the thermoplastic resin film 22b, which is different from a formation position of the through-hole 25, is heated. Since the thermoplastic resin film 22b is attached to the thermosetting resin film 21b while heating and pressurizing the position in the thermoplastic resin film 22b, which is different from the formation position of the through-hole 25, blockage of the through-hole 25 can be restrained. Thus, the stud bump 52a and the pad 31 can be in the pressure welding state in a short time in mounting the semiconductor chip 50 on the substrate.

In the present embodiment, the example in which each of the multiple through-holes 25 is formed for the corresponding one pad 31 is shown. However, a configuration in which one through-hole 25 is formed for multiple pads 31 may be applied. For example, in the example shown in FIGS. 8A and 8B, the multiple pads 31 are arranged in a shape of a uniserial rectangular ring with ten pads 31 arranged in one side of the rectangular ring, and each of the through-holes 25 is formed for each side, i.e., each set of ten pads 31. That is, the through-hole 25 has a shape extending in one direction of the perpendicular direction.

Accordingly, compared with the configuration in which one through-hole 25 is formed for one pad 31 as shown in FIGS. 7A and 7B, the through-hole 25 can be formed regardless of the distance (pitch) between the adjacent pads 31. That is, the degree of freedom for the formation of the through-hole 25 is high, and the configuration is suitable for fine pitch.

Hereinbefore, the preferred embodiments of the present invention are described. However, the present invention is not limited to the above-described embodiments, and various changes can be made without departing from the scope of the invention.

The configuration of the multiple resin films constituting the insulating substrate 20 is not limited to the above-described example. The number of the resin films is not limited to the above-described example (eight resin films). The number of the resin films may be arbitrary as long as the semiconductor chip 50 can be embedded in the resin films.

The material for the thermoplastic resin film is not limited to the above-described example. For example, a resin film made of PEEK and PEI having a ratio of PEEK to PEI which is different from that of the above-described example may be used. Furthermore, material other than PEEK and PEI, for example, liquid crystalline polymer (LCP), polyphenylene sulfide (PPS), tetrafluoroethylene-hexafluoropropylene copolymer (FEP), tetrafluoroethylene-perfluoro (alkyl vinyl ether) copolymer (PEA) or the like may be used.

In the above-described embodiments, in order to restrain locally application of stress to the semiconductor chip 50 in the pressurizing and heating process, a film, which does not include inorganic material such as glass fiber and aramid fiber, which is used for a substrate, and inorganic filler for adjusting a melting point and a linear expansion coefficient, is used as the thermoplastic resin films 22a to 22d. However, the thermoplastic resin films 22a to 22d which include the above materials can be used. However, as described above, it is preferable that the thermoplastic resin film (the two thermoplastic resin films 22b, 22c in the above-described embodiments) used for sealing the semiconductor chip 50 does not include inorganic material such as glass fiber and aramid fiber, which is used for a substrate, and inorganic filler for adjusting a melting point and a linear expansion coefficient so as to restrain locally application of stress to the semiconductor chip 50.

The material for the thermosetting resin film is not limited to the above-described example. For example, a film that includes inorganic material such as glass fiber and aramid fiber, which is used for a substrate, can be used. Furthermore, thermosetting resin other than thermosetting polyimide can be used.

The multiple resin films may include only thermoplastic resin films without including thermosetting resin films. Moreover, the number of thermoplastic resin films may be larger than that of thermosetting resin films. In this case, in a part of the resin films, the thermoplastic resin films are adjacent to each other in the stacked state.

In the above-described embodiments, the thermosetting resin film 21b as the first film is used as the substrate on which the semiconductor chip 50 is flip-chip mounted. However, a thermoplastic resin film may be used as the first film. In addition, multiple resin films including the first film may serve as the substrate.

In the above-described embodiments, in order to improve a heat releasing property, the heat releasing member 60 is fixed to the surface 20b of the insulating substrate 20. Likewise, in order to improve the heat releasing property, the dummy electrode 51c is formed on the semiconductor chip 50, and the heat-releasing wiring part (the pad 33 and the interlayer connecting portion 42) is connected to the dummy electrode 51c. However, the configuration in which at least one of the heat releasing member 60 and the heat-releasing wiring part is not formed may be applied. In the configuration in, which either one of the heat releasing member 60 and the heat-releasing wiring part is formed, the heat releasing property can be improved, although inferior to the configuration shown in FIG. 1 compared to the configuration in which both of them are not formed.

The heat releasing member 60 is formed on the whole of the surface 20b of the insulating substrate 20. However, the heat releasing member 60 may be fixed to a part of the surface 20b or may be formed on both of the surfaces 20a, 20b of the insulating substrate 20.

In the above-described embodiments, the semiconductor chip 50 has the electrodes 51 on both surfaces thereof, and the electrodes 51 include the electrodes 51a, 51b, which provide the electrically connecting function and the dummy electrode 51c. However, the dummy electrode 51c as well as the heat-releasing wiring part may not be formed. Furthermore, the electrodes 51 may be formed on only one surface of the semiconductor chip 50 as long as the electrodes 51 include at least the electrode 51a on which the stud bump 52a is formed.

For example, the configuration in which the semiconductor chip 50 has the electrode 51a on one surface thereof and the dummy electrode 51c on the opposite surface thereof may be applied. In this case, as described above, if the electrical connection between the dummy electrode 51c and the pad 33 is formed by the liquid-phase diffusion, the pressure (press pressure) applied to the semiconductor chip 50 in the pressurizing and heating process can be restrained.

The configuration in which the semiconductor chip 50 has the electrode 51 (51a) on one surface thereof and no electrode on the opposite surface thereof may be applied. In this case, the wiring part and the heat-releasing wiring part are not connected to the surface on which the electrode 51 is not formed. Thus, compared with the configuration in which the electrodes 51 are formed on both surfaces of the semiconductor chip 50, the pressure (press pressure) applied to the semiconductor chip 50 can be restrained in the pressurizing and heating process by the softened thermoplastic resin film 22c.

Furthermore, the thickness of the resin film and the thickness of the conductive pattern 30 are not limited to the above-described example. However, it is preferable that each of the thermoplastic resin films 22b, 22c, which is adjacent to the semiconductor chip 50 in the stacking direction and seals the semiconductor chip 50, has a thickness of equal to or larger than 5 μm.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element are also within the spirit and scope of the invention.

What is claimed is:

1. A manufacturing method of a semiconductor chip-embedded wiring substrate comprising:
stacking a plurality of resin films and a plurality of thermoplastic resin films including thermoplastic resin to form a stacked body, wherein the plurality of resin films include a resin film having a conductive pattern on a surface thereof and a resin film having a via hole filled with a conductive paste, at least one of the plurality of resin films is located between adjacent two thermoplastic resin films, an electrode formation surface of a semiconductor chip contacts one of the plurality of thermoplastic resin films and an opposite surface of the electrode formation surface of the semiconductor chip contacts another one of the plurality of thermoplastic resin films, and the semiconductor chip is sandwiched between the one of the plurality of thermoplastic resin films and the another one of the plurality of thermoplastic resin films;
pressurizing and heating the stacked body from upper and lower sides of the stacked body in a stacking direction to form a wiring part including the conductive pattern and a sintered body formed by sintering conductive particles in the conductive paste, wherein the plurality of thermoplastic resin films are softened to integrate the plurality of resin films with the plurality of thermoplastic resin films at one time and seal the semiconductor chip;
attaching a second film to a pad formation surface of a substrate including a first film, on a surface of which a pad is formed as a part of the conductive pattern, to cover the pad of the first film with the second film by heating and pressurizing the second film before the stacking, wherein the first film serves as one of the plurality of resin films and the second film serves as one of the plurality of thermoplastic resin films; and
flip-chip mounting the semiconductor chip on the substrate by heating and pressurizing the semiconductor chip at a temperature equal to or higher than a melting point of the thermoplastic resin constituting the second film, wherein a stud bump formed on an electrode of the semiconductor chip is stuffed into the second film while melting the second film and is pressure welded to the pad, and the melted second film seals between the semiconductor chip and the substrate before the stacking wherein
the plurality of resin films and the plurality of thermoplastic resin films other than the one of the plurality of resin films constituting the substrate including the first film and the second film are stacked with the substrate and the second film to form the stacked body in the stacking, and
the stud bump is directly bonded to the pad in the pressurizing and heating the stacked body.

2. The manufacturing method according to claim 1, wherein
the stud bump made of gold is solid-phase diffusion bonded to the pad made of copper in the pressurizing and heating the stacked body.

3. A manufacturing method of a semiconductor chip-embedded wiring substrate comprising:
stacking a plurality of resin films and a plurality of thermoplastic resin films including thermoplastic resin to form a stacked body, wherein the plurality of resin films include a resin film having a conductive pattern on a surface thereof and a resin film having a via hole filled with a conductive paste, at least one of the plurality of resin films is located between adjacent two thermoplastic resin films, an electrode formation surface of a semiconductor chip contacts one of the plurality of thermoplastic resin films and an opposite surface of the electrode formation surface of the semiconductor chip contacts another one of the plurality of thermoplastic resin films, and the semiconductor chip is sandwiched between the one of the plurality of thermoplastic resin films and the another one of the plurality of thermoplastic resin films;
pressurizing and heating the stacked body from upper and lower sides of the stacked body in a stacking direction to form a wiring part including the conductive pattern and a sintered body formed by sintering conductive particles in the conductive paste, wherein the plurality of thermoplastic resin films are softened to integrate the plurality of resin films with the plurality of thermoplastic resin films at one time and seal the semiconductor chip; and
flip-chip mounting the semiconductor chip on a substrate including a first film that serves as one of the plurality of resin films by heating and pressurizing the semiconductor chip, wherein a second film that serves as one of the plurality of thermoplastic resin films is attached to a pad formation surface of the substrate including the first film, on a surface of which a pad is formed as a part of the conductive pattern, to cover the pad of the first film with the second film, the second film has a through-hole at a position corresponding to the pad, the semiconductor chip is heated and pressurized at a temperature equal to or higher than a melting point of the thermoplastic resin constituting the second film so that a stud bump formed on an electrode of the semiconductor chip is pressure welded to the pad through the through-hole and the melted second film seals between the semiconductor chip and the substrate before the stacking, wherein
the plurality of resin films and the plurality of thermoplastic resin films other than the one of the plurality of resin films constituting the substrate including the first film and the second film are stacked with the substrate and the second film to form the stacked body in the stacking, and
the stud bump is directly bonded to the pad in the pressurizing and heating the stacked body.

4. The manufacturing method according to claim 3, wherein
the through-hole is one of a plurality of through-holes,
the pad is one of a plurality of pads, and
each of the plurality of through-holes is formed for a corresponding one of the plurality of pads.

5. The manufacturing method according to claim 3, wherein
the pad is one of a plurality of pads, and
the through-hole is formed for the plurality of pads.

6. The manufacturing method according to claim 3, wherein
in the flip-chip mounting, the second film having the through-hole is bonded to the pad formation surface of the substrate by heating and pressurizing a position in the second film which is different from a formation position of the through-hole.

7. The manufacturing method according to claim 3, wherein
in the flip-chip mounting, after the second film is bonded to the pad formation surface of the substrate to cover the pad, the through-hole is formed in the second film at the position corresponding to the pad.

8. The manufacturing method according to claim 3, wherein
the stud bump made of gold is solid-phase diffusion bonded to the pad made of copper in the pressurizing and heating the stacked body.
